(19) United States
(12) Patent Application Publication
(10) Pub. No.: US 2011/0079763 A1
(43) Pub. Date: Apr. 7, 2011

(54) Phase change devices

(76) Inventor: Semyon D. Savransky, Newark, CA (US)

(21) Appl. No.: 12/924,465

(22) Filed: Sep. 28, 2010

Related U.S. Application Data
(60) Provisional application No. 61/278,052, filed on Oct. 2, 2009.

(51) Int. Cl. H01L 45/00

(52) U.S. Cl. 257/2; 257/E45.001

(57) ABSTRACT

The present invention is a phase change device with a heater and a selector (e.g., diode) separated by a phase-change alloy. The present invention will find applicability in electronic memory devices.

### CROSS REFERENCE TO RELATED APPLICATIONS

This application claims priority to and the benefit of, and incorporates herein by reference in its entirety, U.S. Provisional Patent Application No. 61/278,052 which was filed on Oct. 2, 2009.

### PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

1. Field of the Invention

The invention relates to phase-change devices and, in particular, to phase-change memory (PCM).

2. Description of Related Art

Electric resistance of a phase change device varies upon a phase transition of a phase-change alloy (PCA) inside the device between two or more states during the device programming. Phase change device can be read and programmed very quickly and do not require power to maintain their state. Therefore, phase change devices are very useful devices for storing data (e.g., as a computer memory device) and for and configurable electronics. A phase change device constructed from PCA and from a selector (e.g., a transistor or a diode or a Ovshinsky threshold switch or a thyristor or a semiconductor controlled rectifier or a field emitter). Phase change memory (PCM) from plurality of the phase change devices has many of the advantages of both volatile memories such as dynamic random access memories and non-volatile memories such as Flash.

The electric programming pulses produce current that heats up PCA to or above crystallization temperature about 200 deg. C for the low resistance state and to or above melting temperature about 650 deg. C for the high resistive state due to the Joule effect.

One of the device electrodes (usually bottom) is made from a material with poor electrical and thermal conductivities in order to create high temperatures in PCA.

This electrode (so called heater) is deposited between a PCA and a selector as shown in FIG. 1. During programming the heater reach high temperatures that exceed PCA melting temperature. This high temperature negatively affects properties of selectors that degraded with phase change device cycling.

The heater is located between selector and PCA as shown in FIG. 1 according to prior art.

In order to reduce this degradation D. H. Kang et. al. proposed to use heat dissipation layer in the paper “Novel Heat Dissipating Cell Scheme for Improving a Reset Distribution in a 512M Phase-change Random Access Memory (PRAM)” published in Symposium on VLSI Technology Digest of Technical Papers, 2007; p. 96-97. Few technological steps are required to manufacture such devices, hence their cost increases.

What is needed in the art is a phase change device with high endurance.

### BRIEF DESCRIPTION OF THE DRAWINGS

FIG. 1 shows a generic phase-change device known in prior art.

FIG. 2 shows a generic device according to an embodiment of the invention.

### DETAILED DESCRIPTION

The present invention explores a new way to construct a phase-change memory (PCM) that increases its endurance.

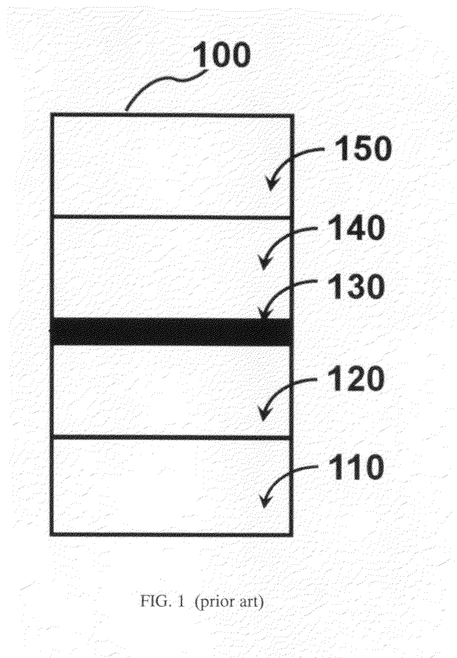

FIG. 1 illustrates a generic device 100 known in prior art. A cell 140 and a selector 120 are located between bitline 210 and wordline 150. A heater 130 located between the cell 140 and the selector 120 provides possibility of the phase-change cell 140 programming into one of the logic states due to Joule heating propagated from the heater 130 to the cell 140. Because the heater 130 is located in close proximity to the selector 120 high temperatures negatively affect the properties of selector 120, for example change p−n junctions in the selector 120. As the result endurance of the device 100 is low that prevents it usage in high-reliability memory applications.

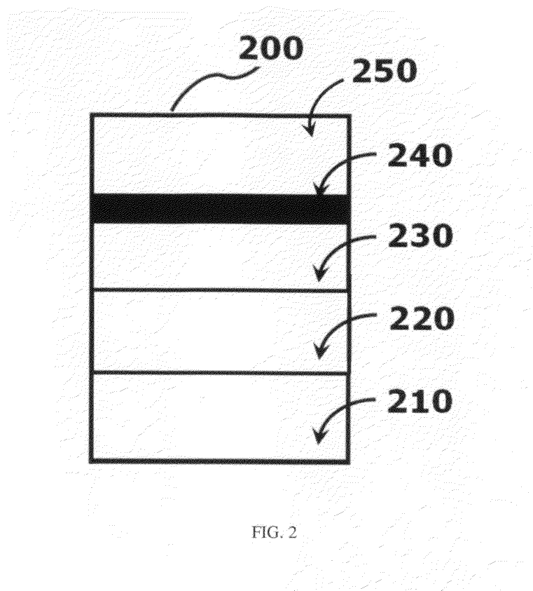

FIG. 2 illustrates a generic device 200, according to an embodiment of the invention. An active cell 230 and a selector 220 are located between a first electrode (so called bitline) 210 and a second electrode (so called wordline) 250. A heater 240 located between the cell 140 and the wordline 250 provides possibility of the cell 230 programming into one of the logic states due to Joule heating propagated from the heater 240 to the cell 230. Because the heater 240 is located in far away from the selector 120 and due to small thermal conductivity of the cell 230 the selector 220 does not expose to high temperatures during the cell 230 programming. As the result endurance of the device 200 is high.

In some embodiments at least one electrical conductor is located between the cell 230 and the selector 220, or between the bitline 210 and the selector 220, or between the wordline 250 and the heater 240.

In some embodiments at least one electrical insulator is used to reduce contact area between the heater 240 and the cell 230, or to separate one device 200 from another device 200 in a circuit, or to reduce contact area between the cell 230 and the selector 220.

Devices 200 can be used in non-volatile and electrical memory or in configurable electronics (e.g. in programmable gate arrays).

The bitline 210 and the wordline 250 can be made from a good electrical and thermal conductor, e.g. Al or Cu.

The memory cell 230 consists of at least one phase change alloy with a small thermal conductivity, e.g. Ge-Sb-Te or In-Sb-Te.
The heater 240 consists of at least one material with moderate electrical and thermal conductivity, e.g. TaSiN or TiSiAl or TiN.
An electrical insulator can be made from SiO2 or Si3N4.

The device 200 or/and apparatus containing at least one of the devices 200 can be produced by methods well known in semiconductor manufacturing.

### Conclusion

The main advantage of this invention is high endurance of phase change devices due to insulation of a selector to exposure to high temperatures during a cell programming.

To summarize, various embodiments of a phase-change devices have been described. In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

Although a preferred embodiment of the present invention has been described for illustrative purposes, those skilled in the art will appreciate that various modifications, additions and substitutions are possible, without departing from the scope and spirit of the invention as disclosed in the accompanying main claims.

I claim:

1. A phase change device comprising:
a first electrode;
a selector;
a phase change cell formed on at least a portion of an upper surface of the selector;
a heater formed on at least a portion of an upper surface of the cell;
and a second electrode formed on at least a portion of an upper surface of the heater.

2. The device of claim 1, wherein a phase change alloy in the cell has a small thermal conductivity.

3. The device of claim 1, wherein the selector is a diode or a transistor or an Ovshinsky threshold switch or a field emitter.

4. The device of claim 1, wherein the heater is insulated from the selector by the phase change cell.

5. The device of claim 1, wherein an electrical insulator is formed on a portion of an upper surface of the cell.

6. An apparatus comprising at least one electrical circuit coupled with the device of claim 1.
